(19) United States
(12) Patent Application Publication
(10) Pub. No.: US 2025/0284259 A1
(43) Pub. Date: Sep. 11, 2025

(54) BATTERY SYSTEM OPERATION

(71) Applicant: Analog Devices International Unlimited Company, Limerick (IE)

(72) Inventors: Claire Nelia LEVEUGLE, Mallow (IE); Michael O'Brien, Munster (IE); Frank Yaul, Somerville, MA (US); Shane O'Mahony, Grenagh (IE); Hemant Kumar, Munchen (DE)

(21) Appl. No.: 19/216,322

(22) Filed: May 22, 2025

Related U.S. Application Data
(63) Continuation-in-part of application No. 18/789,088, filed on Jul. 30, 2024.
(60) Provisional application No. 63/520,464, filed on Aug. 18, 2023.
(60) Provisional application No. 63/650,587, filed on May 22, 2024.
(60) Provisional application No. 63/665,573, filed on Jun. 28, 2024.
(60) Provisional application No. 63/686,636, filed on Aug. 23, 2024.

(51) Int. Cl. G05B 17/02; H01M 10/42

(52) U.S. Cl. CPC G05B 17/02; H01M 10/425; H01M 2010/4271

(57) ABSTRACT

The technology disclosed herein may establish a data representation of the physical geometry of a battery assembly, the battery assembly comprising a plurality of cells, one or more power connections, an electrochemical impedance spectroscopy (EIS) controller, EIS force conductors, and EIS sense conductors. The technology may define simulation port positions at each connection between EIS force/sense conductors and each cell, and at each connection of EIS sense conductors to the EIS controller. The technology may model the EIS sense circuitry and the EIS force circuitry. The technology may simulate EIS response across a frequency range using the established data representation, established simulation port positions, and the modeled EIS sense circuitry and force circuitry, producing S-parameters corresponding to each established simulation port. The technology may adjust the complex impedance of the particular cell as a function of the S-parameters.

### CROSS-REFERENCE TO RELATED APPLICATIONS

This application is a Continuation-in-Part of and claims priority to U.S. Non-Provisional patent application Ser. No. 18/789,088 filed Jul. 30, 2024 and entitled “BATTERY SYSTEM OPERATION”; which claims the benefit of (i) U.S. Provisional Pat. App. No. 63/520,464 filed Aug. 18, 2023 and entitled “BATTERY SYSTEM MONITORING,” (ii) U.S. Provisional Pat. App. No. 63/650,587 filed May 22, 2024 and entitled “BATTERY SYSTEM MEASUREMENT AND OPERATION,” and (iii) U.S. Provisional Pat. App. No. 63/665,573 filed Jun. 28, 2024 and entitled “BATTERY SYSTEM MEASUREMENT AND OPERATION.” This application claims the benefit of U.S. Provisional Pat. App. No. 63/686,636 filed Aug. 23, 2024 and entitled “DETECTION OF BATTERY SYSTEM ANOMALIES USING EIS.” The disclosure of each of the above application is hereby incorporated herein in its entirety.

### FIELD OF THE DISCLOSURE

This disclosure relates to battery system operation, generally. More specifically, the disclosure describes technology for operating and controlling battery systems through one or more of simulation, measurement calibration, high temperature measurement, and measurement adjustment.

### BACKGROUND

Electrochemical impedance spectroscopy (EIS) may be used to characterize electrochemical systems such as single cells, batteries comprising one or more cells, and battery assemblies (including measurement and control equipment). EIS may measure the complex impedance of one or more cells over a range of frequencies—using the measurements to characterize, inter alia, energy state, storage, and dissipation properties of the cell(s), battery, or battery assembly. The data obtained through EIS can be represented in Bode plots or Nyquist plots.

The complex impedance includes a real/resistive component and an imaginary/reactive component. Such complex impedance can be measured as a universal dielectric response, whereby EIS reveals a power law relationship between the impedance and the frequency ω of an applied alternating current (AC) forcing function across a range a frequencies. Such current may be applied using a pair of force wires, and the impedance may be measured using at least one set of sense wires, often one pair of sense wires across each cell. The converse approach to measuring impedance can also be used, i.e., a voltage can be forced and a resulting current can be observed.

### SUMMARY OF THE DISCLOSURE

In some aspects, the techniques described herein relate to a computer-implemented method of battery operation, the method including: establishing, by one or more processors, a data representation of the physical geometry of a battery assembly, the battery assembly including a plurality of cells, one or more power connections, an electrochemical impedance spectroscopy (EIS) controller, EIS force conductors, and EIS sense conductors; defining, by one or more processors, simulation port positions at each connection between EIS force/sense conductors and each cell, and at each connection of EIS sense conductors to the EIS controller; modeling, by one or more processors, the EIS sense circuitry and the EIS force circuitry; simulating, by the one or more processors, EIS response across an EIS frequency range using the established data representation, the established simulation port positions, and the modeled EIS sense circuitry and force circuitry, producing S-parameters corresponding to each established simulation port; and adjusting, by one or more processors, the complex impedance of the particular cell as a function of the S-parameters.

In some aspects, the techniques described herein relate to a system including: a memory storing instructions therein; and one or more processors communicatively coupled with the memory, the one or more processors being configured to execute the instructions to: establish, by one or more processors, a data representation of the physical geometry of a battery assembly, the battery assembly including a plurality of cells, one or more power connections, an electrochemical impedance spectroscopy (EIS) controller, EIS force conductors, and EIS sense conductors; define, by one or more processors, simulation port positions at each connection between EIS force/sense conductors and each cell, and at each connection of EIS sense conductors to the EIS controller; model, by one or more processors, the EIS sense circuitry and the EIS force circuitry; simulate, by the one or more processors, EIS response across an EIS frequency range using the established data representation, the established simulation port positions, and the modeled EIS sense circuitry and force circuitry, producing S-parameters corresponding to each established simulation port; and adjust, by one or more processors, the complex impedance of the particular cell as a function of the S-parameters.

In some aspects, the techniques described herein relate to a non-transitory computer-readable medium storing computer executable instructions, the instructions when executed by one or more processors in a network operative to: establish, by one or more processors, a data representation of the physical geometry of a battery assembly, the battery assembly including a plurality of cells, one or more power connections, an electrochemical impedance spectroscopy (EIS) controller, EIS force conductors, and EIS sense conductors; define, by one or more processors, simulation port positions at each connection between EIS force/sense conductors and each cell, and at each connection of EIS sense conductors to the EIS controller; model, by one or more processors, the EIS sense circuitry and the EIS force circuitry; simulate, by the one or more processors, EIS response across an EIS frequency range using the established data representation, the established simulation port positions, and the modeled EIS sense circuitry and force circuitry, producing S-parameters corresponding to each established simulation port; and adjust, by one or more processors, the complex impedance of the particular cell as a function of the S-parameters.

### BRIEF DESCRIPTION OF THE DRAWINGS

The present technology will now be described in more detail with reference to the accompanying drawings, which are not intended to be limiting.

FIG. 1 illustrates a typical set of EIS responses (as Nyquist plots) for a eight standalone cells, in accordance with examples of the technology disclosed herein, in accordance with examples of the technology disclosed herein.

FIG. 2 illustrates a typical set of EIS responses (as Nyquist plots) for a plurality of cells arranged into a battery assembly with EIS force and sense conductor(s) in situ in a production unit of an end system, in accordance with examples of the technology disclosed herein.

FIG. 3 illustrates a set of adjusted EIS responses for some cells of FIG. 2, in situ in a production unit of the end system using the battery assembly, in accordance with examples of the technology disclosed herein.

FIG. 4 illustrates a battery assembly including a battery of four cells and EIS measurement equipment, in accordance with examples of the technology disclosed herein.

FIG. 5 illustrates Nyquist plots for the battery assembly of FIG. 4 and two other battery assemblies, in accordance with examples of the technology disclosed herein.

FIG. 6 illustrates three views of currents and magnetic fields (H-field) for the battery assembly of FIG. 4 at 1 KHz, in accordance with examples of the technology disclosed herein.

FIG. 7 is a block diagram of methods of battery operation, in accordance with examples of the technology disclosed herein.

FIG. 8 illustrates a data representation and port definition, in accordance with examples of the technology disclosed herein.

FIG. 9 illustrates example results associated with EIS simulation, measurement, and adjustment, in accordance with examples of the technology disclosed herein.

FIG. 10 illustrates a Nyquist plot of cell impedance at different temperatures, in accordance with examples of the technology disclosed herein.

FIG. 11 is a block diagram illustrating methods for pre-production and production training in accordance with examples of the technology disclosed herein.

FIG. 12 is a block diagram illustrating methods for adjusting EIS of cell(s) measured at individual condition(s) to an EIS at reference condition(s), in accordance with examples of the technology disclosed herein.

FIG. 13 illustrates three battery modules on a manufacturing line, in accordance with examples of the technology disclosed herein.

FIG. 14 schematically illustrates a device that may serve as a computer, processor, host, etc., in accordance with examples of the technology disclosed herein.

### DETAILED DESCRIPTION

In the following detailed description, reference is made to the accompanying drawings which form a part hereof wherein like numerals designate like parts throughout, and in which is shown by way of illustration examples that may be practiced. It is to be understood that other examples may be utilized, and structural or logical changes may be made, without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described example. Various additional operations may be performed and/or described operations may be omitted in additional examples.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

Various components may be referred to or illustrated herein in the singular (e.g., a “processor,” a “peripheral device,” etc.), but this is simply for case of discussion, and any element referred to in the singular may include multiple such elements in accordance with the teachings herein.

The description uses the phrases “in an example” or “in examples,” which may each refer to one or more of the same or different examples. Furthermore, the terms “comprising,” “including,” “having,” and the like, as used with respect to examples of the present disclosure, are synonymous. As used herein, the term “circuitry” may refer to, be part of, or include an application-specific integrated circuit (ASIC), an electronic circuit, and optical circuit, a processor (shared, dedicated, or group), and/or memory (shared, dedicated, or group) that execute one or more software or firmware programs, a combinational logic circuit, and/or other suitable hardware that provide the described functionality.

Electrochemical systems include both galvanic and electrolytic electrochemical systems such as vehicle batteries, fuel cells, electrochemical capacitors, bio-electrochemical systems, electrochemical sensors, corrosion cells, photo chemical cells, thermos-galvanic cells, and electrochromic system, and can be individual cells or batteries of cells. The technology disclosed herein, while illustrated with respect to galvanic batteries of one or more cells, applies to electrochemical systems in general.

EIS can be used as a tool for generating insights into battery operation in systems such as electric vehicles (EVs), energy storage systems, and various consumer systems. As the dimensions of individual cells become larger, their impedance starts to reduce. This impedance reduction can become further compounded as original equipment manufacturers (OEMs) increase the number of cells connected in parallel in a battery. Such impedance reduction, regardless of the reason, may cause other factors, such as parasitic impedance effects from EIS force wires and sense wires, mutual inductance between cells, skin effect, and eddy currents to affect, even dominate, raw EIS measurements. Consider that OEMs are generally restricted with the physical arrangement/form-factors used for battery system (including EIS measurement components) design. This often makes it impractical for an OEM to offer optimal (from an EIS perspective) cable routing in an end use system, such as a vehicle—hence likely increasing the effect of such other factors on EIS measurements. Unless accounted for, such effects may severely impact the performance of EIS-based algorithms.

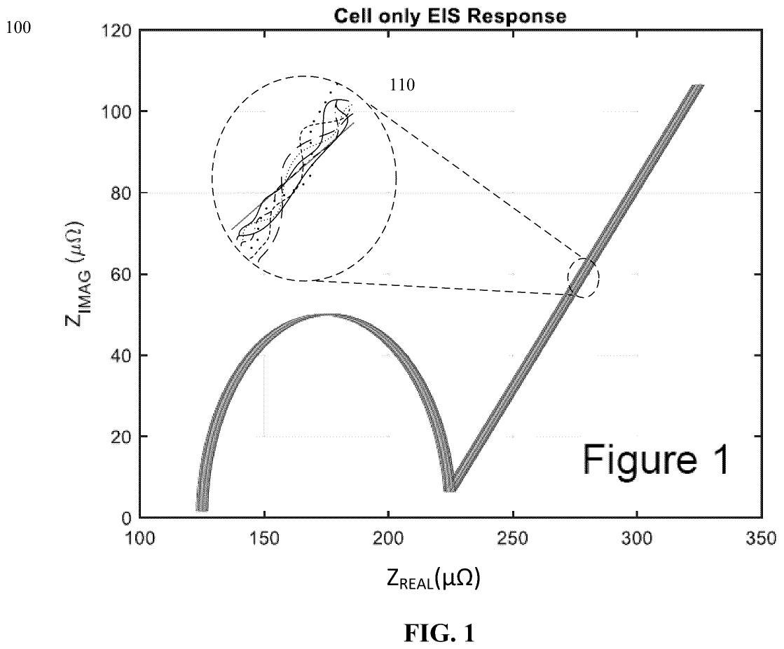

Referring to FIG. 1, a typical set of EIS Nyquist responses 100 for a plurality, eight in this case, of standalone cells (cells tested in isolation from each other, and in low electromagnetic noise environments) is illustrated, in accordance with examples of the technology disclosed herein. The represented cells are each at a similar operating point, e.g., same state-of-charge (SoC), same temperature, and same age. Given that each cell is in a similar state and no other cells are interfering with the measurement (e.g. lab conditions and cable routing are controlled as best as practical), the EIS responses (real and imaginary impedance) of each cell align very closely—within minor expected cell-to-cell variation, e.g., as illustrated in inset 110. In general, data points to the upper right correspond to lower frequencies of the EIS response of the cell, and points proceeding counterclockwise from the upper right correspond to higher frequencies of the EIS response to the cell.

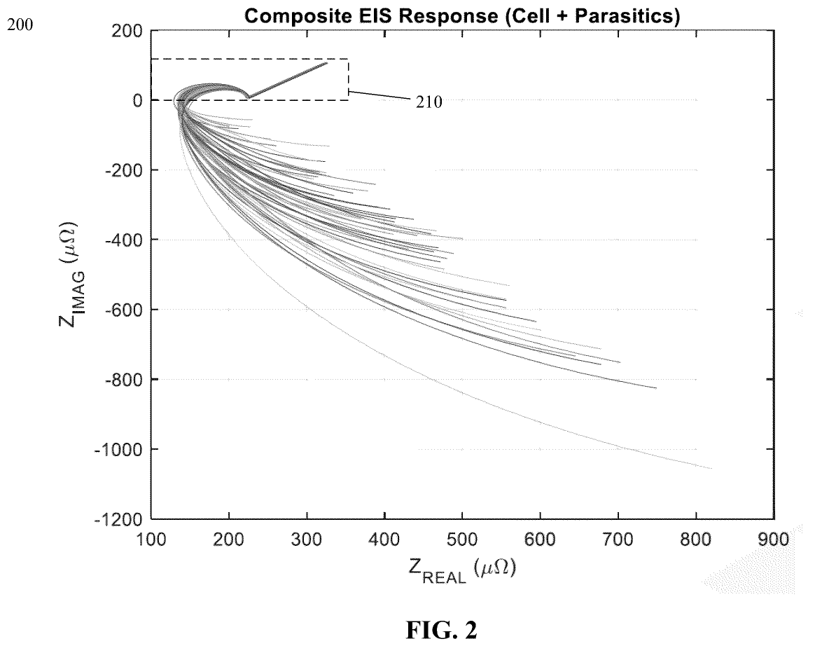

Referring to FIG. 2, a typical set of EIS responses 200 for a plurality of cells with EIS force and sense conductor(s) in situ in a production unit of an end system is illustrated, in accordance with examples of the technology disclosed herein. Box 210 approximates the scale of the real and imaginary axes of FIG. 1. Inside box 210, it can be seen that the data for each cell begins to vary from that of FIG. 1 as the frequency of the forcing function increases, and then increasingly varies from each other outside of box 210. It can be difficult to engineer an EIS-based algorithm for battery operation from such noisy/skewed data.

On type of solution accounts for the effect of factors such as such as parasitic impedance effects from EIS force wires and sense wires, mutual inductance between cells, skin effect, and eddy currents on raw EIS measurements-either with or without attributing the adjustments to any particular factor. The adjusted EIS measurements can be used to control operation of the battery, e.g., controlling charging periods based on SoC determined using EIS, controlling cell temperature, controlling cell pressure. The adjusted EIS measurements can be reported to other processes that use the information to monitor and control battery and end-use system operation.

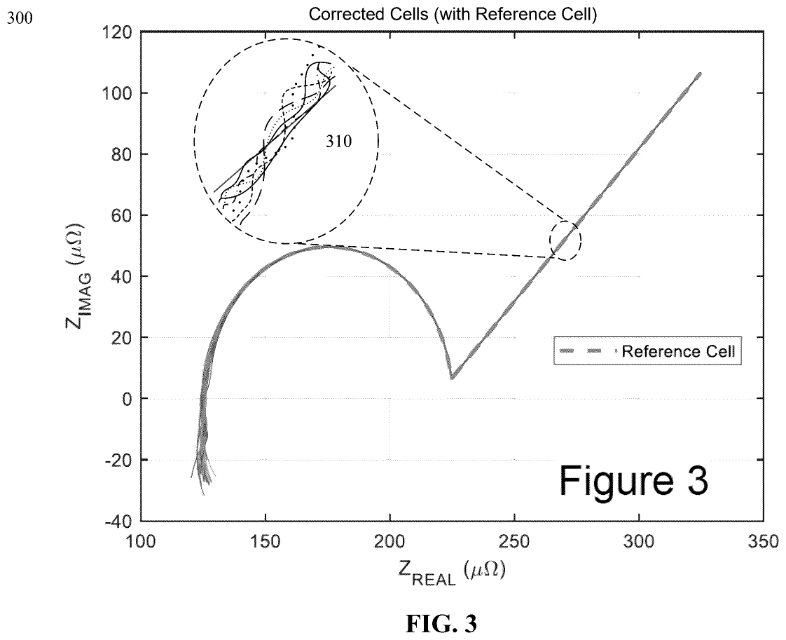

Referring to FIG. 3, and continuing to refer to prior figures for context, a set of adjusted EIS responses 300 for some cells of FIG. 2, in situ in a production unit of the end system using the battery assembly is illustrated, in accordance with examples of the technology disclosed herein. In FIG. 3, a reference complex impedance and a model complex impedance were used to adjust the raw EIS values collected as depicted in FIG. 2. Inset 310 illustrates minor remaining variations.

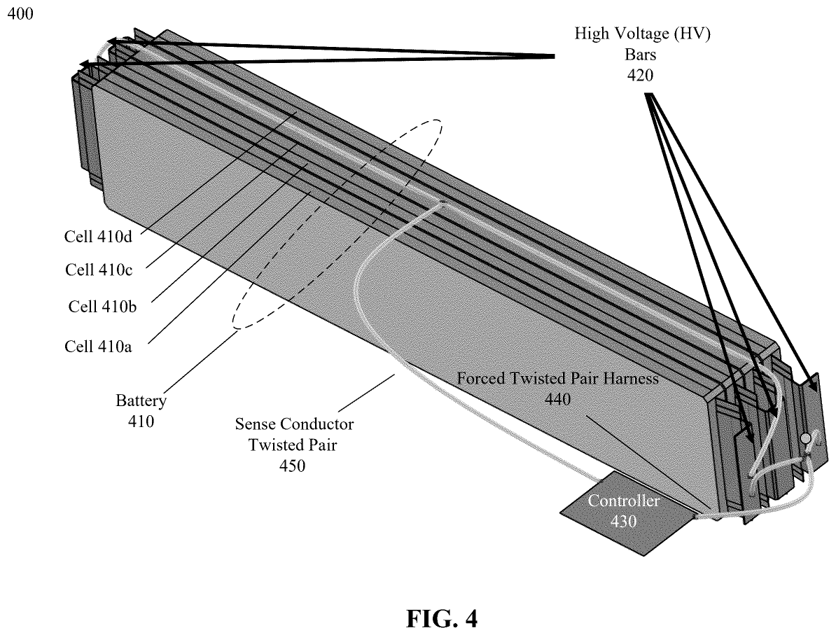

Referring to FIG. 4, and continuing to refer to prior figures for context, a battery assembly 400 including a battery 410 (of four cells 410a-410d) and EIS measurement equipment 430, 440, 450 is shown, in accordance with examples of the technology disclosed herein. The four cells 410a-410d are connected in series by high voltage (HV) bars 420 to form the battery 410. The EIS measurement equipment includes a controller 430, force conductors 440, and sense conductors 450. The conductors are shown in this example battery assembly 400 as twisted pairs, but can be single conductors with a ground return in appropriate circumstances.

The controller 430 transmits an AC forcing function over a set of force conductors 440 that are split near the right side HV bars 420 and then connected across the series-connected cells 410a to 410d. While the force conductors 440 in this example are a twisted pair, other conductors can be used. The forcing function can be any signal that contains the EIS frequencies of interest, e.g., a step pulse, a series of step pulses, a swept wave, a square wave, a series of combined individual sinusoids at different frequencies, and a stochastic broadband signal. The controller 430 independently senses the first cell 410a using a set of twisted pair of sense conductors 450 that are split to connect across the first cell 410a—only the sense conductors 450 for the first cell 410a are shown in this example. Note that twisted pair sense conductors 450 cross the first cell 410a and second cell 410b before splitting over the third cell 410c. As noted above, in some examples, a converse approach to measuring impedance can also be used, i.e., a voltage can be forced and a resulting current can be observed. In each case, as long as the forcing function covers the frequencies of interest, either sinusoidal or non-sinusoidal functions can be used.

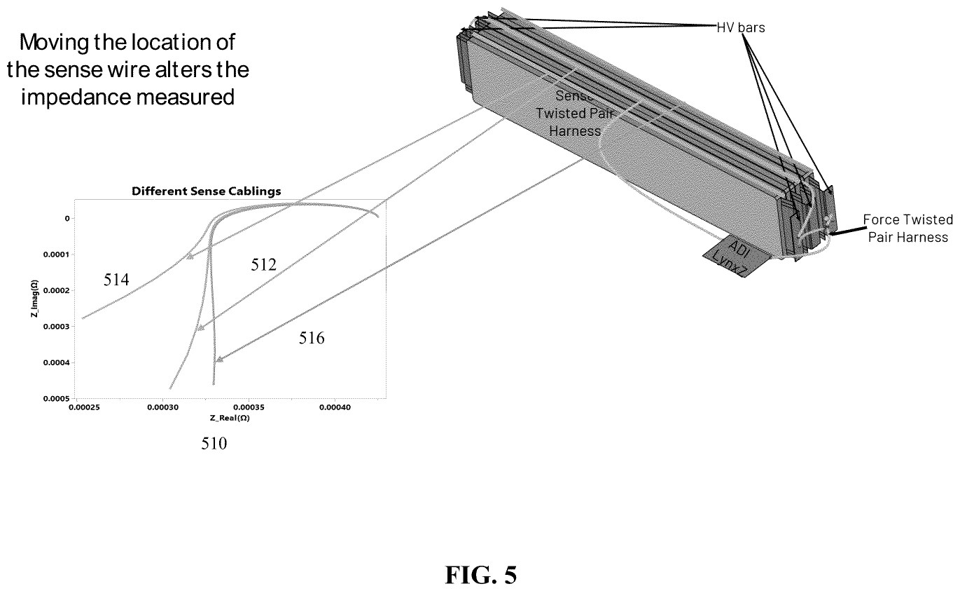

Referring to FIG. 5, and continuing to refer to prior figures for context, Nyquist plots 510 for the sense conductor routing of battery assembly 400 across the third cell 410c (corresponding to Nyquist plot 512), and two other sense conductor 450 routings (same cells, controller, HV bars) are illustrated, in accordance with examples of the technology disclosed herein. In one other routing, the split of sense conductors 450 is routed over the first cell 410a alone. The Nyquist plot 514 corresponding to the routing of sense conductors 450 across cell 410a shows lower real impedance as the frequency of the forcing function increases when compared to the Nyquist plot 512 for the routing of battery assembly 400. In yet another routing, the sense conductors 450 are routed across each of the first cell 410a, the second cell 410b, and the third cell 410c before splitting over the fourth cell 410d. The Nyquist plot 516 corresponding to that routing shows higher real impedance as the frequency of the forcing function increases when compared to the Nyquist plot 512 for battery assembly 400. FIG. 5 illustrates the possible dramatic influence of measurement equipment routing on the raw EIS data.

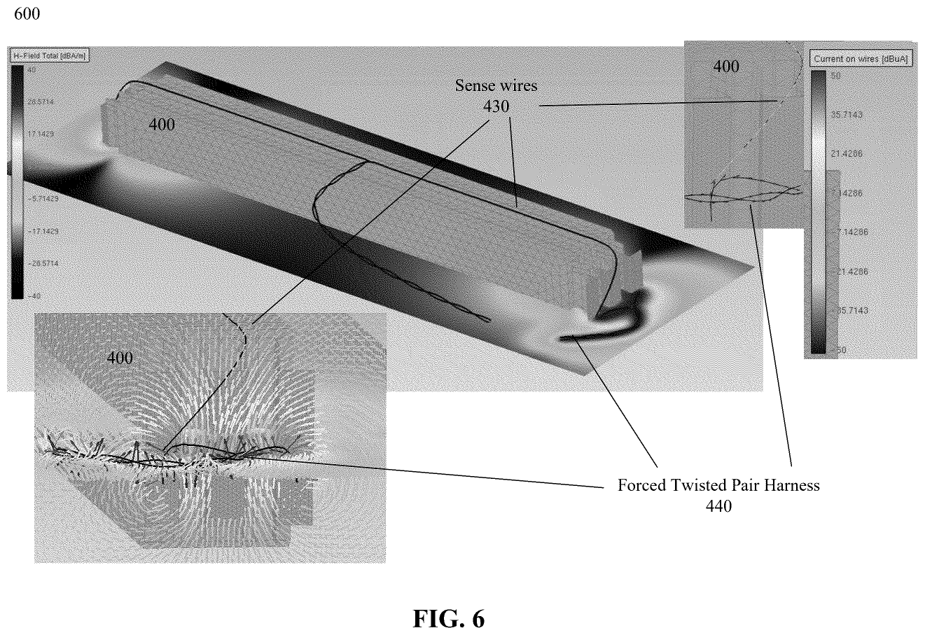

Referring to FIG. 6 and continuing to refer to prior figures for context, three views 600 of currents and magnetic fields (H-field) for battery assembly 400 at 1 kHz are illustrated, in accordance with examples of the technology disclosed herein. In the views 600, sense conductors 450 can be seen to be exposed to H field of the force conductors 440 and carry currents induced by such H fields.

There are applications where it is useful to supplement EIS with other approaches to manage battery operation. In such applications, one or more of simulation, measurement calibration, high temperature measurement, and compensation can be used to adjust raw EIS measurements. When battery management and operation involves training, battery assembly parasitics can be part of the training data pool.

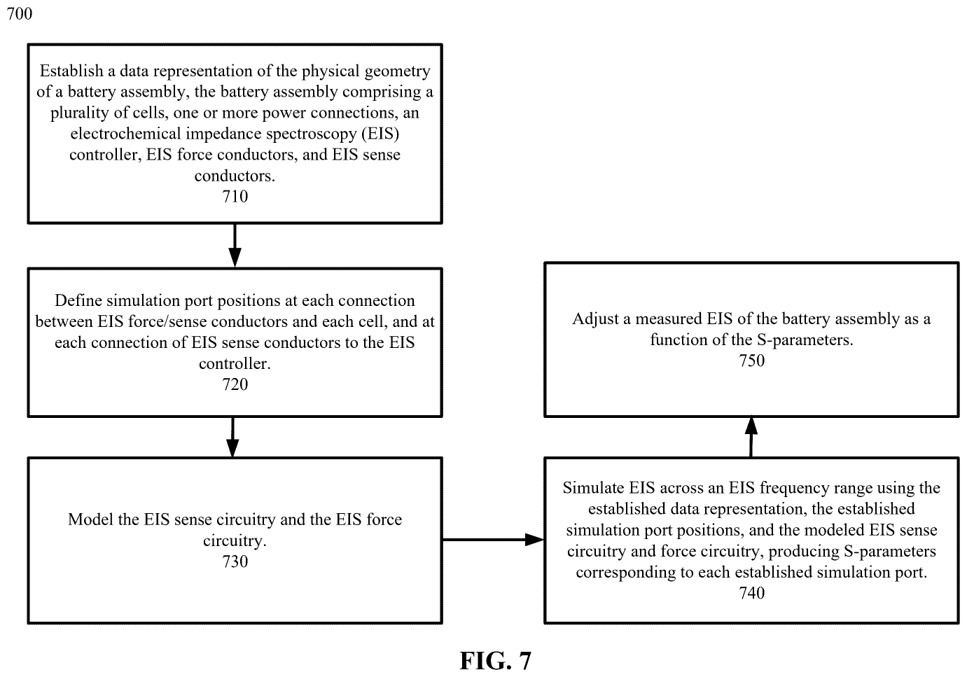

Referring to FIG. 7, and continuing to refer to prior figures for context, computer-implemented methods 700 for adjusting electrochemical impedance spectroscopy (EIS) measurements of a battery assembly are illustrated, in accordance with examples of the technology disclosed herein.

In such methods 700, using one or more processors, a data representation of the physical geometry of a battery assembly is established—Block 710. The battery assembly includes a plurality of cells, one or more power connections associated with the cells, an electrochemical impedance spectroscopy (EIS) controller, EIS force conductors, and EIS sense conductors. In a first continuing example, a computer-aided drafting model of the battery assembly, including the wiring harness, is established for the battery assembly 400 of FIG. 4.

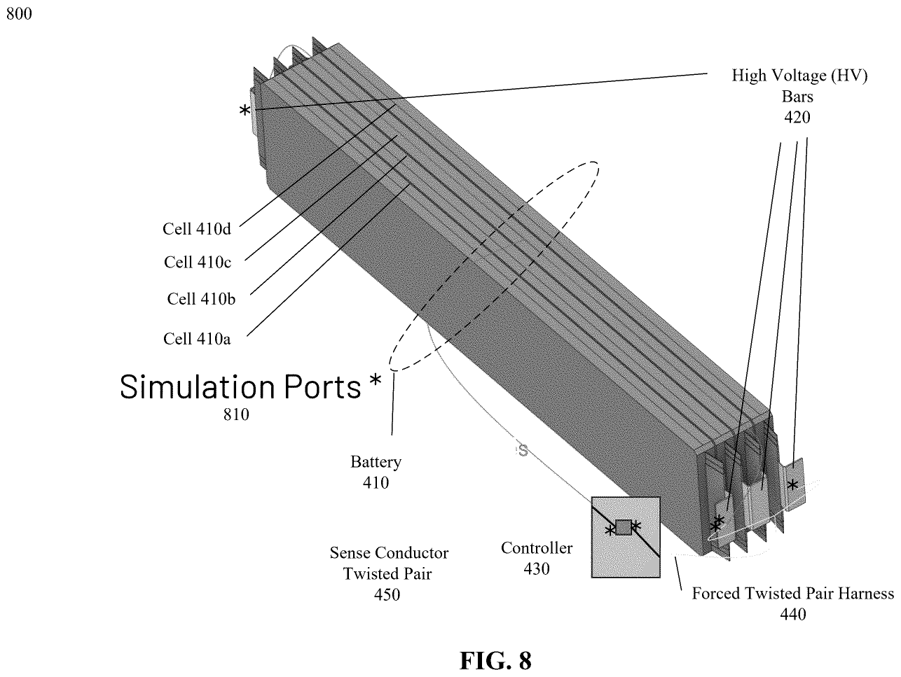

Using the one or more processors, simulation port positions are defined at each connection between the EIS force/sense conductors and each cell, and at each connection of EIS sense conductors to the EIS controller—Block 720. Referring to FIG. 8, and continuing to refer to prior figures for context, an example 800 of the data representation and port definition of the first continuing example is shown, in accordance with examples of the technology disclosed herein. In the example 800, simulation ports 810 are defined at each side of controller 430 and at the high voltage bars 420 where the force conductors 440 are connected.

Using the one or more processors, the EIS sense circuitry and the EIS force circuitry are modelled—Block 730.

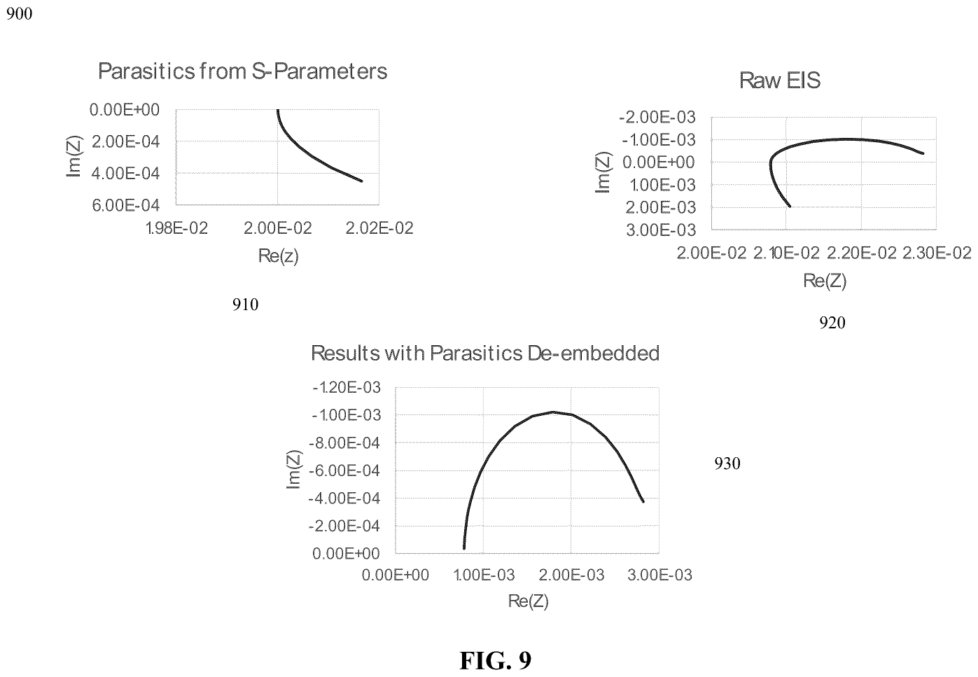

Using the one or more processors, EIS characteristics of the battery assembly are simulated across an EIS frequency range using the established data representation, the established simulation port positions, and the modeled EIS sense circuitry and force circuitry, producing S-parameters corresponding to each established simulation port—Block 740. Referring to FIG. 9, and continuing to refer to prior figures for context, example results 900 associated with EIS simulation, measurement, and adjustment, in accordance with examples of the technology disclosed herein. In particular, graph 910 illustrates S-parameters collected across frequencies of a simulated forcing signal in the continuing example.

Using the one or more processors, a measured EIS characteristic of the battery assembly is adjusted as a function of the S-parameters—Block 750. In the continuing example, graph 920 illustrates raw measured EIS for the battery assembly 400 of FIG. 4 in situ, e.g., installed in a vehicle. Graph 930 illustrates the adjusted EIS after subtracting the S-parameter results of graph 910 from the raw EIS results of graph 920. In some examples, the raw EIS data can also be simulation data or data of a representative model of battery assembly 400.

In some examples, EIS measurements can be adjusted to account for parasitic effects using measurement calibration. In some such examples, a measurement set-up calibration such as short-open-load-through (SLOT) calibration, typically part of a vector network analyzer (VNA) can be used.

A VNA is an instrument used to measure the network parameters of electrical networks. It is particularly useful for characterizing the behavior of RF and components by measuring their scattering parameters (S-parameters). VNAs are capable of measuring both the magnitude and phase of the electrical signals, providing a comprehensive analysis of the network's response. In EIS, a VNA can be used to accurately measure the impedance of the system by analyzing how the system responds to a range of frequencies. The VNA's ability to measure both magnitude and phase makes it ideal for capturing the complex impedance characteristics of electrochemical systems. In some examples, the technology includes using a VNA capable of low frequency measurements to perform calibration on the battery assembly, and then de-embedding the results attributable to the EIS components.

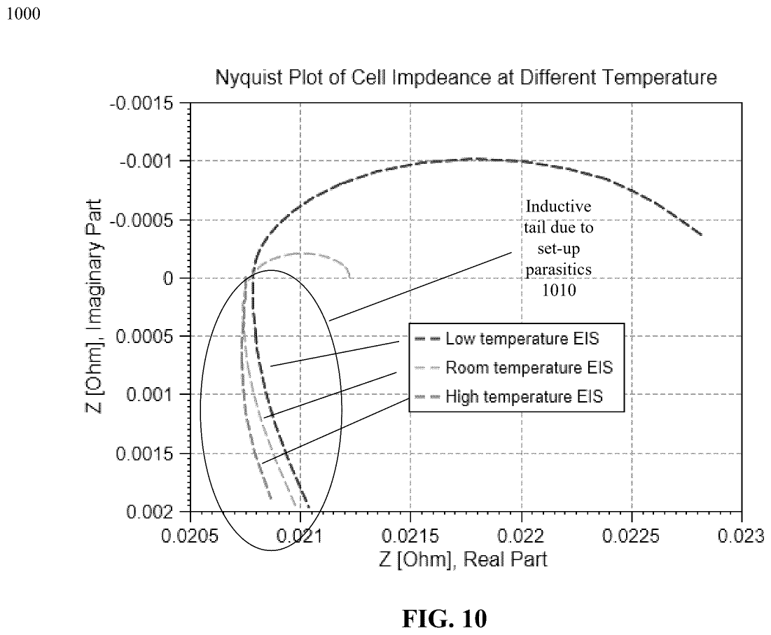

In some examples, EIS measurements can be adjusted to account for parasitic effects using high temperature measurements. In some such examples, EIS measurements are taken at different temperatures, including temperatures well above and well below room temperature. Referring to FIG. 10, and continuing to refer to prior figures for context, a Nyquist plot 1000 of cell impedance at different temperatures is shown, in accordance with examples of the technology disclosed herein. As the temperature of the cell increases, its capacitive region decreases, leaving resistive elements as well as set-up parasitics as can be seen in the inductive tail 1010 at high temperature. Some examples of the technology disclosed herein subtract the imaginary part of the high temperature cell impedance from the cells impedance at other temperatures—allowing removal of the inductive element of the set-up from the measured cell inductance at all temperatures.

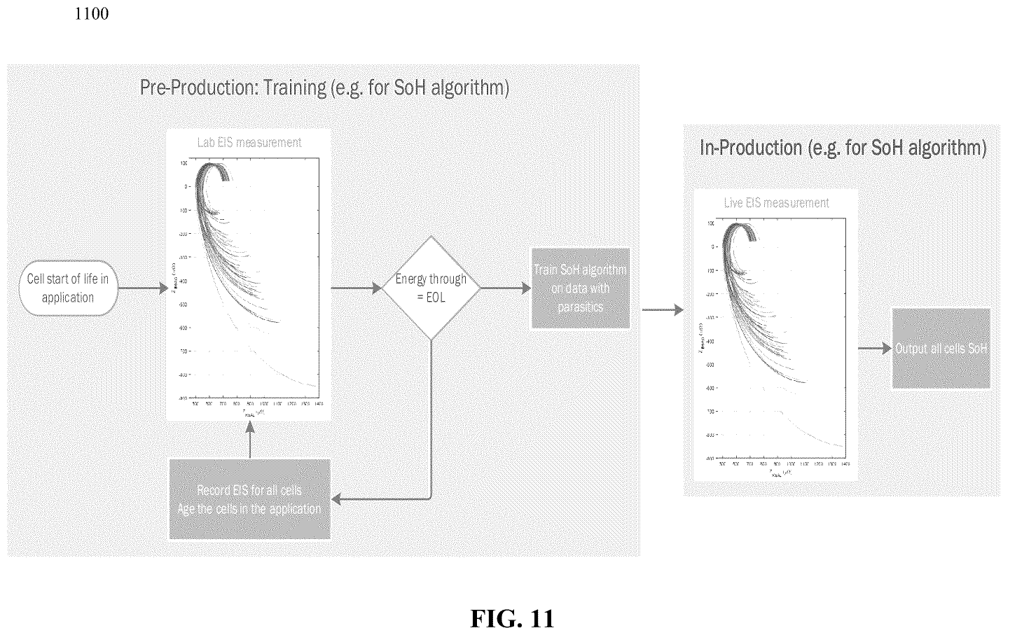

In some examples, an approach to ascertain cell characteristics using EIS, an algorithm training phase may be useful. Performing the training on cells with set-up parasitics using EIS as described in the applications incorporated herein by reference can reduce the impact of the parasitics on the EIS-based algorithm output. Referring to FIG. 11, and continuing to refer to prior figures for context, a block diagram 1100 for pre-production and production training is illustrated, in accordance with examples of the technology disclosed herein. In some such examples, the EIS of a group of cells (e.g., a battery pack) is measured using EIS as described in the applications incorporated herein. The desired output (e.g., SoH) is trained on data from all the cells, with raw EIS (including parasitics) as input.

In some examples, EIS data gathered under first conditions (first SoC, first temperature) can be mapped or adjusted to EIS data under reference conditions—thus allowing a more apples-to-apples comparison of EIS data from various conditions as though collected under the common reference conditions. Such an approach can allow, among other things, determining if one or more cells, batteries, assemblies, modules, or packs are within manufacturing or operating tolerances.

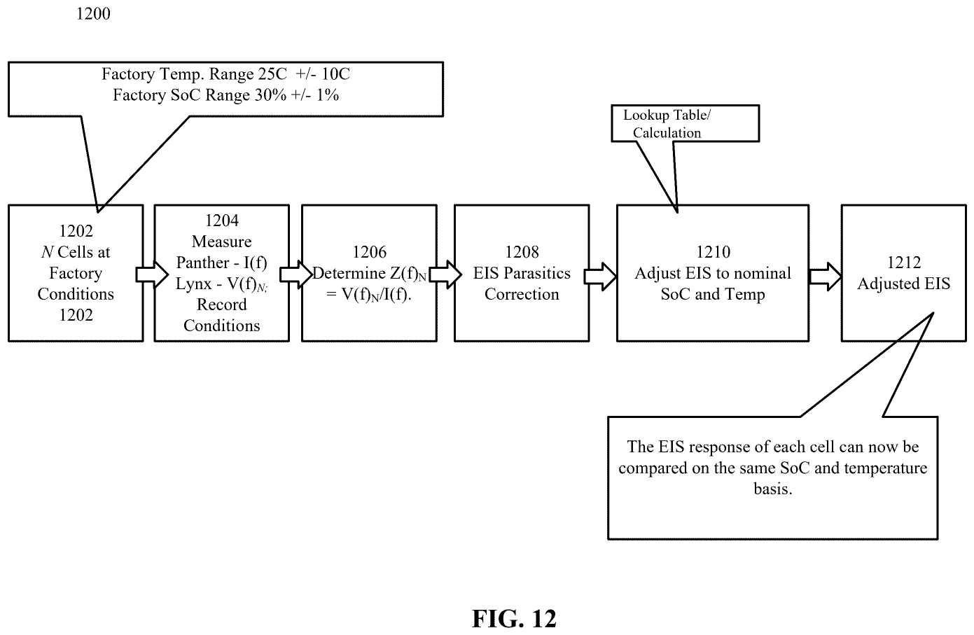

Referring to FIG. 12, and continuing to refer to prior figures for context, a block diagram illustrating methods 1200 for adjusting EIS of cell(s) measured at individual condition(s) to an EIS at reference condition(s) is illustrated, in accordance with examples of the technology disclosed herein.

In such methods 1200, a number N of cells (N≥1) are at factory conditions of temperature (25C +/−10C in this example) and state of charge (SoC) (30% +/−1%)-—lock 1202. Though in general, such range restriction is not required, e.g., the range across the population of cells can be unknown. In addition, other cell characteristics/conditions such as ambient humidity and ambient pressure can also be used.

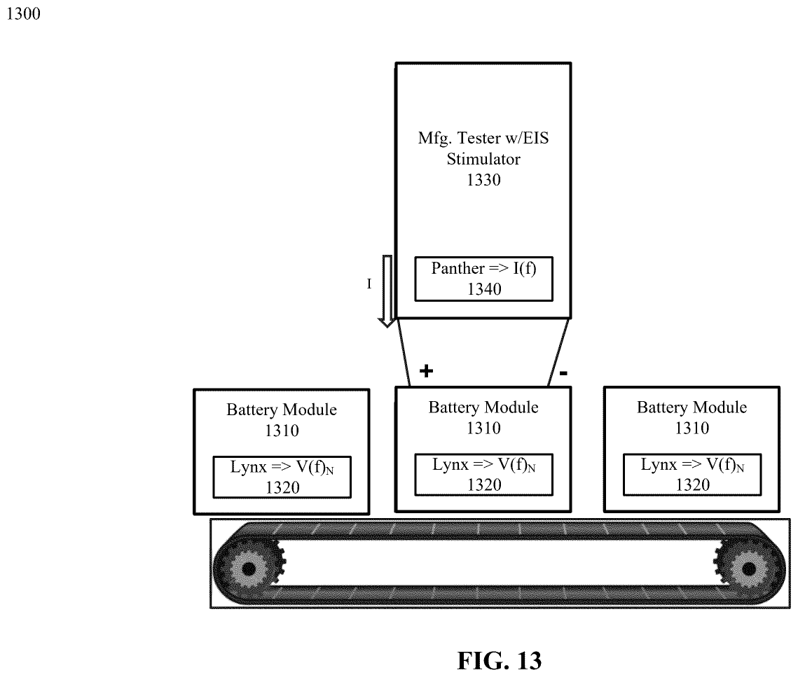

A plurality of such cells can form a battery assembly, module, or pack. Referring to FIG. 13, and continuing to refer to prior figures for context, an example of three battery modules 1310 on a manufacturing line are shown. Each battery module includes a voltage sensing portion (a Lynx device 1320). A manufacturing test stimulator 1330 including a current forcing/sensing portion (a Panther device 1340) is included therein.

In the present example, the battery module 1310 includes a plurality of cells in series, along with cabling, sensors, and processors (Lynx 1320) for determining the complex voltage across each cell over a frequency range, V(f)_{N}, while cabling, sensors, and processors (Panther 1340) for applying and measuring a complex current, I(f), is separate factory equipment outside of the module 1310. The placement of equipment for measuring V(f)_{N} and I(f) can be different, e.g., both sets of equipment can be embedded with the battery assembly, module, or pack; both sets of equipment can be factory equipment applied to measure each battery assembly, module, or pack.

In such methods 1200, an I(f) is applied by Panther 1340 across frequencies of interest to module 1310 and the conditions of interest (in this case temperature and SoC) are recorded—Block 1204. In such methods 1200, the raw complex impedance Z(f)_{N} is determined as V(f)_{N}/I(f)—Block 1206.

In such methods 1200, technology such as that disclosed in the applications incorporate by reference herein can be used to “correct” the EIS data to mitigate the effects of parasitics on EIS data; resulting in “corrected” EIS data, Z(f)_{corrected}—Block 1208. In the present example, “corrected” is being used to avoid confusion with the conditions-based adjustment being performed in the next step. Note that though the effects of parasitics on Z(f)_{N} have been mitigated, the effect of other-than-nominal conditions (such as temperature, SoC, humidity, age, etc.) on Z(f)_{corrected} have not yet been addressed. This correction step is not required to receive the benefits of the present example.

In such methods 1200, the “corrected” EIS data can be adjusted/mapped to EIS data for a set of reference conditions—Block 1212. The data for adjusting/mapping EIS data from measured data at an X-tuple of conditions can have been previously collected (e.g., from empirical data) or previously otherwise determined (e.g., from modelling or simulation). For example, a sample set of modules with known EIS characteristics at set of reference conditions can be subject to a set of conditions other than the reference conditions and EIS data can be collected. From the collected other-than-reference-conditions EIS data, a table of adjustments can be determined.

In the present example, such a table of adjustments is indexed on a set of {temperature, SoC} pairs to indicate modifications to Z(f)_{corrected}. In general, for adjustments to Z(f)_{corrected} based on X conditions, the table is indexed on X-tuples of those conditions. In some cases, one or more equations are used to adjust Z(f)_{corrected} of a given call based on X conditions. In some examples, the table(s) and equation(s) are based on lab measurements on a sample set of cells/assemblies/modules/packs of similar or same type as the cells under test.

The adjusted EIS response Z(f)_{adjusted} can be compared to existing data at the reference conditions, e.g., to determine if one or more battery modules 1310 are within manufacturing tolerances even though the manufacturing conditions differ from the reference conditions.

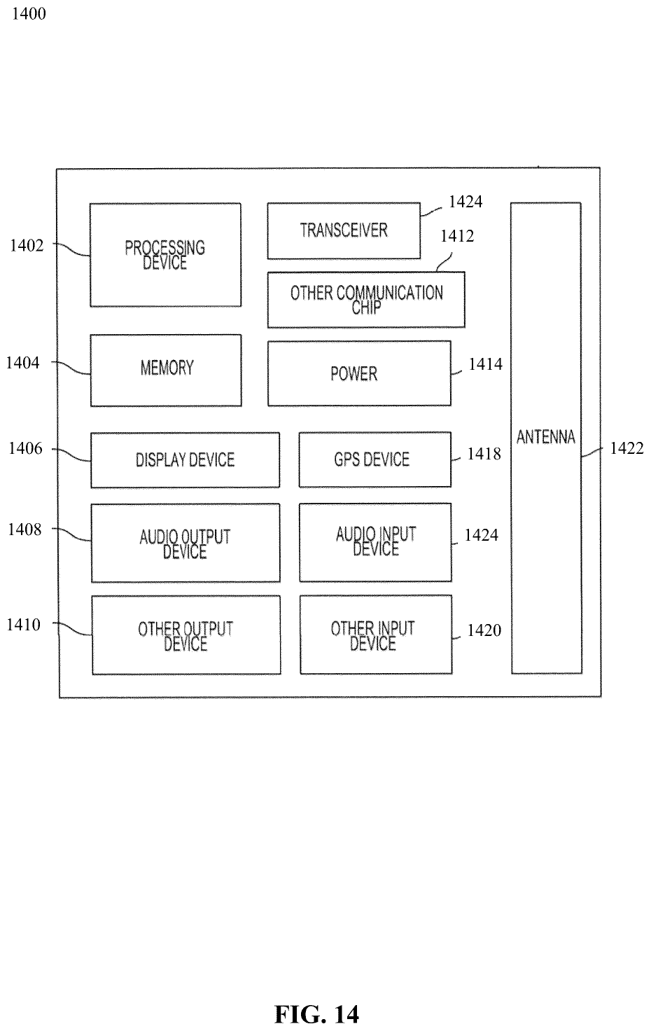

Examples of the present disclosure may be implemented into a system using any suitable hardware and/or software to configure as desired. Referring to FIG. 14, and continuing to refer to prior figures for context, FIG. 14 schematically illustrates a device 1400 that may serve as a computer/processor, in accordance with various examples. A number of components are illustrated in FIG. 14 as included in the device 1400, but any one or more of these components may be omitted or duplicated, as suitable for the application.

Additionally, in various examples, the device 1400 may not include one or more of the components illustrated in FIG. 14, but the device 1400 may include interface circuitry for coupling to the one or more components. For example, the device 1400 may not include a display device 1406, but may include display device interface circuitry (e.g., a connector and driver circuitry) to which a display device 1406 may be coupled. In another set of examples, the device 1400 may not include an audio input device 1424 or an audio output device 1408, but may include audio input or output device interface circuitry (e.g., connectors and supporting circuitry) to which an audio input device 1424 or audio output device 1408 may be coupled.

The device 1400 may include a transceiver 1424, in accordance with any of the examples disclosed herein, for managing communication along the bus when the device 1400 is coupled to the bus. The device 1400 may include a processing device 1402 (e.g., one or more processing devices), which may be included in the node transceiver or separate from the node transceiver. As used herein, the term “processing device” may refer to any device or portion of a device that processes electronic data from registers and/or memory to transform that electronic data into other electronic data that may be stored in registers and/or memory. The processing device 1402 may include one or more DSPs, ASICs, central processing units (CPUs), graphics processing units (GPUs), crypto-processors, or any other suitable processing devices. The device 1400 may include a memory 1404, which may itself include one or more memory devices such as volatile memory (e.g., dynamic random-access memory (DRAM)), non-volatile memory (e.g., read-only memory (ROM)), flash memory, solid state memory, and/or a hard drive.

In some examples, the memory 1404 may be employed to store a working copy and a permanent copy of programming instructions to cause the device 1400 to perform any suitable ones of the techniques disclosed herein. In some examples, machine-accessible media (including non-transitory computer-readable storage media), methods, systems, and devices for performing the above-described techniques are illustrative examples disclosed herein for communication over a two-wire bus. For example, a computer-readable media (e.g., the memory 1404) may have stored thereon instructions that, when executed by one or more of the processing devices included in the processing device 1402, cause the device 1400 to perform any of the techniques disclosed herein.

In some examples, the device 1400 may include another communication chip 1412 (e.g., one or more other communication chips). For example, the communication chip 1412 may be configured for managing wireless communications for the transfer of data to and from the device 1400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some examples they might not.

The communication chip 1412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The one or more communication chips 1412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The one or more communication chips 1412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The one or more communication chips 1412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1412 may operate in accordance with other wireless protocols in other examples. The device 1400 may include an antenna 1422 to facilitate wireless communications and/or to receive other wireless communications (such as AM or FM radio transmissions).

In some examples, the communication chip 1412 may manage wired communications using a protocol other than the protocol for the bus described herein. Wired communications may include electrical, optical, or any other suitable communication protocols. Examples of wired communication protocols that may be enabled by the communication chip 1412 include Ethernet, controller area network (CAN), I2C, media-oriented systems transport (MOST), or any other suitable wired communication protocol.

As noted above, the communication chip 1412 may include multiple communication chips. For instance, a first communication chip 1412 may be dedicated to shorter-range wireless communications such as Wi-Fi or Bluetooth, and a second communication chip 1412 may be dedicated to longer-range wireless communications such as global positioning system (GPS), EDGE, GPRS, CDMA, WiMAX, LTE, EV-DO, or others. In some examples, a first communication chip 1412 may be dedicated to wireless communications, and a second communication chip 1412 may be dedicated to wired communications.

The device 1400 may include battery/power circuitry 1414. The battery/power circuitry 1414 may include one or more energy storage devices (e.g., batteries or capacitors) and/or circuitry for coupling components of the device 1400 to an energy source separate from the device 1400 (e.g., AC line power, voltage provided by a car battery, etc.). For example, the battery/power circuitry 1414 may include the upstream bus interface circuitry and the downstream bus interface circuitry discussed above with reference to FIG. 2 and could be charged by the bias on a bus.

The device 1400 may include a display device 1406 (or corresponding interface circuitry, as discussed above). The display device 1406 may include any visual indicators, such as a heads-up display, a computer monitor, a projector, a touchscreen display, a liquid crystal display (LCD), a light-emitting diode display, or a flat panel display, for example.

The device 1400 may include an audio output device 1408 (or corresponding interface circuitry, as discussed above). The audio output device 1408 may include any device that generates an audible indicator, such as speakers, headsets, or earbuds, for example.

The device 1400 may include an audio input device 1424 (or corresponding interface circuitry, as discussed above). The audio input device 1424 may include any device that generates a signal representative of a sound, such as microphones, microphone arrays, or digital instruments (e.g., instruments having a musical instrument digital interface (MIDI) output).

The device 1400 may include a GPS device 1418 (or corresponding interface circuitry, as discussed above). The GPS device 1418 may be in communication with a satellite-based system and may receive a location of the device 1400, as known in the art.

The device 1400 may include another output device 1410 (or corresponding interface circuitry, as discussed above). Examples of the other output device 1410 may include an audio codec, a video codec, a printer, a wired or wireless transmitter for providing information to other devices, or an additional storage device. Additionally, any suitable ones of the peripheral devices may be included in the other output device 1410.

The device 1400 may include another input device 1420 (or corresponding interface circuitry, as discussed above). Examples of the other input device 1420 may include an accelerometer, a gyroscope, an image capture device, a keyboard, a cursor control device such as a mouse, a stylus, a touchpad, a bar code reader, a Quick Response (QR) code reader, or a radio frequency identification (RFID) reader. Additionally, any suitable ones of the sensors or peripheral devices may be included in the other input device 1420.

Any suitable ones of the display, input, output, communication, or memory devices described above with reference to the device 1400 may serve as the peripheral device in system of the technology disclosed herein. Alternatively or additionally, suitable ones of the display, input, output, communication, or memory devices described above with reference to the device 1400 may be included in a host or a node (e.g., a main node or a sub node).

The elements of a system of the technology disclosed herein may be chosen and configured to provide audio and/or light control over the bus. In some examples, the system of the technology disclosed herein may be configured to serve as a light control system in a vehicle or other environment, with lighting devices (e.g., strip-line light-emitting diodes (LEDs) or other LED arrangements) serving as peripheral devices in communication with nodes along the bus; data may be communicated over the bus to control the color, intensity, duty cycle, and/or or other parameters of the lighting devices. In some examples, the system of the technology disclosed herein may be configured to serve as an audio control system in a vehicle or other environment, with a microphone or other device including an accelerometer that may serve as a peripheral device in communication with a node along the bus; data from the accelerometer may be communicated over the bus 106 to control other peripheral devices along the bus. For example, large spikes in the acceleration data or other predetermined acceleration data patterns may be used to trigger the generation of a sound effect, such as a cowbell or drum hit, by a processing device coupled to a node; that sound effect may be output by a speaker coupled to the processing device and/or by a speaker coupled to another node along the bus. Some examples of the system of the technology disclosed herein may combine any of the lighting control and/or audio control techniques disclosed herein.

Although various ones of the examples discussed above describe the system of the technology disclosed herein in a vehicle setting, this is simply illustrative, and the system of the technology disclosed herein may be implemented in any desired setting. For example, in some examples, a “suitcase” implementation of the system of the technology disclosed herein may include a portable housing that includes the desired components of the system of the technology disclosed herein; such an implementation may be particularly suitable for portable applications, such as portable karaoke or entertainment systems.

Having thus described several aspects and examples of the technology of this application, it is to be appreciated that various alterations, modifications, and improvements will readily occur to those of ordinary skill in the art. Such alterations, modifications, and improvements are intended to be within the spirit and scope of the technology described in the application. For example, those of ordinary skill in the art will readily envision a variety of other means and/or structures for performing the function and/or obtaining the results and/or one or more of the advantages described herein, and each of such variations and/or modifications is deemed to be within the scope of the examples described herein.

Those skilled in the art will recognize or be able to ascertain using no more than routine experimentation, many equivalents to the specific examples described herein. It is, therefore, to be understood that the foregoing examples are presented by way of example only and that, within the scope of the appended claims and equivalents thereto, inventive examples may be practiced otherwise than as specifically described. In addition, any combination of two or more features, systems, articles, materials, kits, and/or methods described herein, if such features, systems, articles, materials, kits, and/or methods are not mutually inconsistent, is included within the scope of the present disclosure.

The foregoing outlines features of one or more examples of the subject matter disclosed herein. These examples are provided to enable a person having ordinary skill in the art (PHOSITA) to better understand various aspects of the present disclosure. Certain well-understood terms, as well as underlying technologies and/or standards may be referenced without being described in detail. It is anticipated that the PHOSITA will possess or have access to background knowledge or information in those technologies and standards sufficient to practice the teachings of the present disclosure.

The PHOSITA will appreciate that they may readily use the present disclosure as a basis for designing or modifying other processes, structures, or variations for carrying out the same purposes and/or achieving the same advantages of the examples introduced herein. The PHOSITA will also recognize that such equivalent constructions do not depart from the spirit and scope of the present disclosure, and that they may make various changes, substitutions, and alterations herein without departing from the spirit and scope of the present disclosure.

The above-described examples may be implemented in any of numerous ways. One or more aspects and examples of the present application involving the performance of processes or methods may utilize program instructions executable by a device (e.g., a computer, a processor, or other device) to perform, or control performance of, the processes or methods.

In this respect, various inventive concepts may be embodied as a computer readable storage medium (or multiple computer readable storage media) (e.g., a computer memory, one or more floppy discs, compact discs, optical discs, magnetic tapes, flash memories, circuit configurations in Field Programmable Gate Arrays or other semiconductor devices, or other tangible computer storage medium) encoded with one or more programs that, when executed on one or more computers or other processors, perform methods that implement one or more of the various examples described above.

The computer readable medium or media may be transportable, such that the program or programs stored thereon may be loaded onto one or more different computers or other processors to implement various ones of the aspects described above. In some examples, computer readable media may be non-transitory media.

Note that the activities discussed above with reference to the FIGURES which are applicable to any integrated circuit that involves signal processing (for example, gesture signal processing, video signal processing, audio signal processing, analog-to-digital conversion, digital-to-analog conversion), particularly those that can execute specialized software programs or algorithms, some of which may be associated with processing digitized real-time data.

In some cases, the teachings of the present disclosure may be encoded into one or more tangible, non-transitory computer-readable mediums having stored thereon executable instructions that, when executed, instruct a programmable device (such as a processor or DSP) to perform the methods or functions disclosed herein. In cases where the teachings herein are embodied at least partly in a hardware device (such as an ASIC, IP block, or SoC), a non-transitory medium could include a hardware device hardware-programmed with logic to perform the methods or functions disclosed herein. The teachings could also be practiced in the form of Register Transfer Level (RTL) or other hardware description language such as VHDL or Verilog, which can be used to program a fabrication process to produce the hardware elements disclosed.

In example implementations, at least some portions of the processing activities outlined herein may also be implemented in software. In some examples, one or more of these features may be implemented in hardware provided external to the elements of the disclosed figures, or consolidated in any appropriate manner to achieve the intended functionality. The various components may include software (or reciprocating software) that can coordinate in order to achieve the operations as outlined herein. In still other examples, these elements may include any suitable algorithms, hardware, software, components, modules, interfaces, or objects that facilitate the operations thereof.

Any suitably configured processor component can execute any type of instructions associated with the data to achieve the operations detailed herein. Any processor disclosed herein could transform an element or an article (for example, data) from one state or thing to another state or thing. In another example, some activities outlined herein may be implemented with fixed logic or programmable logic (for example, software and/or computer instructions executed by a processor) and the elements identified herein could be some type of a programmable processor, programmable digital logic (for example, an FPGA, an erasable programmable read only memory (EPROM), an electrically erasable programmable read only memory (EEPROM)), an ASIC that includes digital logic, software, code, electronic instructions, flash memory, optical disks, CD-ROMs, DVD ROMs, magnetic or optical cards, other types of machine-readable mediums suitable for storing electronic instructions, or any suitable combination thereof.

In operation, processors may store information in any suitable type of non-transitory storage medium (for example, random access memory (RAM), read only memory (ROM), FPGA, EPROM, electrically erasable programmable ROM (EEPROM), etc.), software, hardware, or in any other suitable component, device, clement, or object where appropriate and based on particular needs. Further, the information being tracked, sent, received, or stored in a processor could be provided in any database, register, table, cache, queue, control list, or storage structure, based on particular needs and implementations, all of which could be referenced in any suitable timeframe.

Any of the memory items discussed herein should be construed as being encompassed within the broad term ‘memory.’ Similarly, any of the potential processing elements, modules, and machines described herein should be construed as being encompassed within the broad term ‘microprocessor’ or ‘processor.’ Furthermore, in various examples, the processors, memories, network cards, buses, storage devices, related peripherals, and other hardware elements described herein may be realized by a processor, memory, and other related devices configured by software or firmware to emulate or virtualize the functions of those hardware elements.

Further, it should be appreciated that a computer may be embodied in any of a number of forms, such as a rack-mounted computer, a desktop computer, a laptop computer, or a tablet computer, as non-limiting examples. Additionally, a computer may be embedded in a device not generally regarded as a computer but with suitable processing capabilities, including a personal digital assistant (PDA), a smart phone, a mobile phone, an iPad, or any other suitable portable or fixed electronic device.

Also, a computer may have one or more input and output devices. These devices can be used, among other things, to present a user interface. Examples of output devices that may be used to provide a user interface include printers or display screens for visual presentation of output and speakers or other sound generating devices for audible presentation of output. Examples of input devices that may be used for a user interface include keyboards, and pointing devices, such as mice, touch pads, and digitizing tablets. As another example, a computer may receive input information through speech recognition or in other audible formats.

Such computers may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks or wired networks.

Computer-executable instructions may be in many forms, such as program modules, executed by one or more computers or other devices. Generally, program modules include routines, programs, objects, components, data structures, etc. that performs particular tasks or implement particular abstract data types. Typically, the functionality of the program modules may be combined or distributed as desired in various examples.

The terms “program” or “software” are used herein in a generic sense to refer to any type of computer code or set of computer-executable instructions that may be employed to program a computer or other processor to implement various aspects as described above. Additionally, it should be appreciated that according to one aspect, one or more computer programs that when executed perform methods of the present application need not reside on a single computer or processor, but may be distributed in a modular fashion among a number of different computers or processors to implement various aspects of the present application.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

When implemented in software, the software code may be executed on any suitable processor or collection of processors, whether provided in a single computer or distributed among multiple computers.

Computer program logic implementing all or part of the functionality described herein is embodied in various forms, including, but in no way limited to, a source code form, a computer executable form, a hardware description form, a computer-implemented method with memory storing code/instructions therein, and various intermediate forms (for example, mask works, or forms generated by an assembler, compiler, linker, or locator). In an example, source code includes a series of computer program instructions implemented in various programming languages, such as an object code, an assembly language, or a high-level language such as OpenCL, RTL, Verilog, VHDL, Fortran, C, C++, JAVA, or HTML for use with various operating systems or operating environments. The source code may define and use various data structures and communication messages. The source code may be in a computer executable form (e.g., via an interpreter), or the source code may be converted (e.g., via a translator, assembler, or compiler) into a computer executable form.

In some examples, any number of electrical circuits of the FIGURES may be implemented on a board of an associated electronic device. The board can be a general circuit board that can hold various components of the internal electronic system of the electronic device and, further, provide connectors for other peripherals. More specifically, the board can provide the electrical connections by which the other components of the system can communicate electrically. Any suitable processors (inclusive of digital signal processors, microprocessors, supporting chipsets, etc.), memory elements, etc. can be suitably coupled to the board based on particular configuration needs, processing demands, computer designs, etc.

Other components such as external storage, additional sensors, controllers for audio/video display, and peripheral devices may be attached to the board as plug-in cards, via cables, or integrated into the board itself. In another example, the electrical circuits of the FIGURES may be implemented as standalone modules (e.g., a device with associated components and circuitry configured to perform a specific application or function) or implemented as plug-in modules into application-specific hardware of electronic devices.

Note that with the numerous examples provided herein, interaction may be described in terms of two, three, four, or more electrical components. However, this has been done for purposes of clarity and example only. It should be appreciated that the system can be consolidated in any suitable manner. Along similar design alternatives, any of the illustrated components, modules, and elements of the FIGURES may be combined in various possible configurations, all of which are clearly within the broad scope of this disclosure.

In certain cases, it may be easier to describe one or more of the functionalities of a given set of flows by only referencing a limited number of electrical elements. It should be appreciated that the electrical circuits of the FIGURES and its teachings are readily scalable and can accommodate a large number of components, as well as more complicated/sophisticated arrangements and configurations. Accordingly, the examples provided should not limit the scope or inhibit the broad teachings of the electrical circuits as potentially applied to a myriad of other architectures.

Also, as described, some aspects may be embodied as one or more methods. The acts performed as part of the method may be ordered in any suitable way. Accordingly, examples may be constructed in which acts are performed in an order different than illustrated, which may include performing some acts simultaneously, even though shown as sequential acts in illustrative examples.

All definitions, as defined and used herein, should be understood to control over dictionary definitions, definitions in documents incorporated by reference, and/or ordinary meanings of the defined terms. Unless the context clearly requires otherwise, throughout the description and the claims: “comprise,” “comprising,” and the like are to be construed in an inclusive sense, as opposed to an exclusive or exhaustive sense; that is to say, in the sense of “including, but not limited to.” “Connected,” “coupled,” or any variant thereof, means any connection or coupling, either direct or indirect, between two or more elements. The coupling or connection between the elements can be physical, logical, or a combination thereof. “Herein,” “above,” “below,” and words of similar import, when used to describe this specification shall refer to this specification as a whole and not to any particular portions of this specification. “Or,” in reference to a list of two or more items, covers all of the following interpretations of the word: any of the items in the list, all of the items in the list, and any combination of the items in the list. The singular forms “a,” “an” and “the” also include the meaning of any appropriate plural forms.

Words that indicate directions such as “vertical”, “transverse”, “horizontal”, “upward”, “downward”, “forward”, “backward”, “inward”, “outward”, “vertical”, “transverse”, “left”, “right”, “front”, “back”, “top”, “bottom”, “below”, “above”, “under”, and the like, used in this description and any accompanying claims (where present) depend on the specific orientation of the apparatus described and illustrated. The subject matter described herein may assume various alternative orientations. Accordingly, these directional terms are not strictly defined and should not be interpreted narrowly.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined.

Elements other than those specifically identified by the “and/or” clause may optionally be present, whether related or unrelated to those elements specifically identified. Thus, as a non-limiting example, a reference to “A and/or B”, when used in conjunction with open-ended language such as “comprising” may refer, in one example, to A only (optionally including elements other than B); in another example, to B only (optionally including elements other than A); in yet another example, to both A and B (optionally including other elements); etc.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

Thus, as a non-limiting example, “at least one of A and B” (or, equivalently, “at least one of A or B,” or, equivalently “at least one of A and/or B”) may refer, in one example, to at least one, optionally including more than one, A, with no B present (and optionally including elements other than B); in another example, to at least one, optionally including more than one, B, with no A present (and optionally including elements other than A); in yet another example, to at least one, optionally including more than one, A, and at least one, optionally including more than one, B (and optionally including other elements); etc.

As used herein, the term “between” is to be inclusive unless indicated otherwise. For example, “between A and B” includes A and B unless indicated otherwise.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

Numerous other changes, substitutions, variations, alterations, and modifications may be ascertained to one skilled in the art and it is intended that the present disclosure encompass all such changes, substitutions, variations, alterations, and modifications as falling within the scope of the appended claims.

In order to assist the United States Patent and Trademark Office (USPTO) and, additionally, any readers of any patent issued on this application in interpreting the claims appended hereto, Applicant wishes to note that the Applicant: (a) does not intend any of the appended claims to invoke 35 U.S.C. § 112(f) as it exists on the date of the filing hereof unless the words “means for” or “steps for” are specifically used in the particular claims; and (b) does not intend, by any statement in the disclosure, to limit this disclosure in any way that is not otherwise reflected in the appended claims.

The present invention should therefore not be considered limited to the particular examples described above. Various modifications, equivalent processes, as well as numerous structures to which the present invention may be applicable, will be readily apparent to those skilled in the art to which the present invention is directed upon review of the present disclosure.

It should be understood that the detailed description and specific examples, while indicating examples of the systems and methods are intended for purposes of illustration only and are not intended to limit the scope. These and other features, aspects, and advantages of the systems and methods of the present invention can be better understood from the description, appended claims or aspects, and accompanying drawings. It should be understood that the Figures are merely illustrative and are not drawn to scale. It should also be understood that the same reference numerals are used throughout the figures to indicate the same or similar parts.

Other variations to the disclosed examples can be understood and effected by those skilled in the art in practicing the disclosure, from a study of the drawings, the disclosure, and the appended aspects or claims. In the aspects or claims, the word “comprising” does not exclude other elements or steps, and the indefinite article “a” or “an” does not exclude a plurality. The mere fact that certain measures are recited in mutually different dependent aspects or claims does not indicate that a combination of these measures cannot be used to advantage. Any reference signs in the claims should not be construed as limited the scope.

What is claimed is:

1. A computer-implemented method of battery operation, the method comprising:
establishing, by one or more processors, a data representation of a physical geometry of a battery assembly, the battery assembly comprising a plurality of cells, one or more power connections, and electrochemical impedance spectroscopy (EIS) equipment, the EIS equipment comprising an electrochemical impedance spectroscopy (EIS) controller, EIS force conductors, and EIS sense conductors;
defining, by one or more processors, simulation port positions at each connection between EIS force/sense conductors and each cell, and at each connection of EIS sense conductors to the EIS controller;
modeling, by one or more processors, the EIS sense conductors and the EIS equipment;
simulating, by the one or more processors, EIS response across an EIS frequency range using the established data representation, the established simulation port positions, and the modeled EIS sense circuitry and force circuitry, producing S-parameters corresponding to each established simulation port; and
adjusting, by one or more processors, a complex impedance of each cell as a function of the S-parameters.

2. A system comprising:
a memory storing instructions therein; and
one or more processors communicatively coupled with the memory, the one or more processors being configured to execute the instructions to:
establish, by one or more processors, a data representation of a physical geometry of a battery assembly, the battery assembly comprising a plurality of cells, one or more power connections, and electrochemical impedance spectroscopy (EIS) equipment, the EIS equipment comprising an electrochemical impedance spectroscopy (EIS) controller, EIS force conductors, and EIS sense conductors;
define, by one or more processors, simulation port positions at each connection between EIS force/sense conductors and each cell, and at each connection of EIS sense conductors to the EIS controller;
model, by one or more processors, the EIS sense conductors and the EIS equipment;
simulate, by the one or more processors, EIS response across an EIS frequency range using the established data representation, the established simulation port positions, and the modeled EIS sense circuitry and force circuitry, producing S-parameters corresponding to each established simulation port; and
adjust, by one or more processors, a complex impedance of each cell as a function of the S-parameters.

3. A non-transitory computer-readable medium storing computer executable instructions, the instructions when executed by one or more processors in a network operative to:
establish, by one or more processors, a data representation of a physical geometry of a battery assembly, the battery assembly comprising a plurality of cells, one or more power connections, and electrochemical impedance spectroscopy (EIS) equipment, the EIS equipment comprising an electrochemical impedance spectroscopy (EIS) controller, EIS force conductors, and EIS sense conductors;
define, by one or more processors, simulation port positions at each connection between EIS force/sense conductors and each cell, and at each connection of EIS sense conductors to the EIS controller;
model, by one or more processors, the EIS sense conductors and the EIS equipment;
simulate, by the one or more processors, EIS response across an EIS frequency range using the established data representation, the established simulation port positions, and the modeled EIS sense circuitry and force circuitry, producing S-parameters corresponding to each established simulation port; and
adjust, by one or more processors, a complex impedance of each cell as a function of the S-parameters.
